(19) United States
(12) Patent Application Publication
(10) Pub. No.: US 2026/0190654 A1
(43) Pub. Date: Jul. 2, 2026

(54) DISPLAY PANEL

(71) Applicant: LG Display Co., Ltd., Seoul (KR)

(72) Inventors: Mi Hee SHIN, Paju-si (KR); Se Hwan NA, Paju-si (KR)

(73) Assignee: LG Display Co., Ltd., Seoul (KR)

(21) Appl. No.: 19/431,778

(22) Filed: Dec. 23, 2025

(30) Foreign Application Priority Data
Dec. 31, 2024 (KR) 10-2024-0203030

(51) Int. Cl. H10K 59/123; H10K 59/121; H10K 59/88

(52) U.S. Cl. CPC H10K 59/123; H10K 59/1213; H10K 59/88

(57) ABSTRACT

A display panel includes a substrate including a first display region and a second display region adjacent to each other. The first display region includes a plurality of first pixel units and a plurality of transmissive portions between the plurality of first pixel units, each first pixel unit including a first light-emitting element configured to emit a first color light and a transistor for driving the first light-emitting element. The second display region includes a plurality of second pixel units, each including a first regular light-emitting element configured to emit the first color light and a transistor for driving the first regular light-emitting element. A number of contact holes disposed between the first light-emitting element and the transistor for driving the first light-emitting element is greater than a number of contact holes disposed between the first regular light-emitting element and the transistor for driving the first regular light-emitting element.

### CROSS-REFERENCE TO RELATED APPLICATION

This application claims priority to and the benefit of Korean Patent Application No. 10-2024-0203030, filed on Dec. 31, 2024, the disclosure of which is incorporated herein by reference in its entirety.

### BACKGROUND

### Field of the Specification

The present specification relates to a display panel.

### Discussion of Related Art

The field of display devices for visually displaying electrical information signals is rapidly developing while entering the full-fledged information age. Accordingly, research for developing such performance attributes as a thinner profile, a reduced weight, and low power consumption for various display devices is continuing.

Specific examples of display devices include a liquid crystal display device (LCD), an organic light-emitting display device (OLED), a quantum dot display device, and the like.

Recently, the multimedia function of mobile terminals is being enhanced. For example, organic light-emitting display devices with built-in optical electronic devices on the front have been developed.

For the camera units and sensor units located in a display region in the front of the display device, a design of a full-screen display is being proposed by implementing an under display camera (UDC), an under panel sensor (UPS), and under display infrared radiation (UDIR) so that they are not recognized by users for aesthetic reasons. To this end, as pixel units and transmissive portions are disposed together in the camera units and the various sensor units, the recognition rate of sensors and the aesthetic appeal for users are being enhanced.

In this case, design efforts for reducing a difference in brightness between light-emitting elements in a general region of a display panel and light-emitting elements in an UDC region are being made.

### SUMMARY

The number of transistors disposed per unit area in camera units and various sensor units represented as an under display camera (UDC) and under display infrared radiation (UDIR) region of a display panel is relatively smaller compared to a high-resolution region which is a general region. Thus, the number of contact holes, which are connection portions between the transistors and light-emitting units, naturally decreases in the UDC and UDIR region. Thereafter, during post-processing, a difference in elements of the general display region and the UDC and UDIR region occurs due to a difference in the number of physical contact holes.

Accordingly, the present specification is directed to a display panel that substantially obviates one or more of the problems due to limitations and disadvantages of the related art.

In the display panel according to one or more example embodiments of the present specification, additional dummy contact holes are disposed in the UDC and UDIR region and a configuration patterned in a pixel unit is minimized or reduced. Thus, the display panel according to one or more example embodiments of the present specification can reduce a difference in brightness between the general region and the UDC and UDIR region.

The objects according to embodiments of the present specification are not limited to the above-described objects, and other objects that are not mentioned can be clearly understood by those skilled in the art from the following description.

To achieve these objects and other advantages of the present disclosure, as embodied and broadly described herein, a display panel according to one or more embodiments of the present specification includes a substrate including a first display region and a second display region adjacent to the first display region, the first and second display regions each being configured to display an image. The first display region may include a plurality of first pixel units and a plurality of transmissive portions between the plurality of first pixel units, each of the plurality of first pixel units including a first light-emitting element configured to emit a first color light and a transistor for driving the first light-emitting element. The second display region may include a plurality of second pixel units, each including a first regular light-emitting element configured to emit the first color light and a transistor for driving the first regular light-emitting element. A number of contact holes disposed between the first light-emitting element and the transistor for driving the first light-emitting element in the first display region may be greater than a number of contact holes disposed between the first regular light-emitting element and the transistor for driving the first regular light-emitting element in the second display region.

In another aspect of the present disclosure, a display apparatus includes: a substrate with a first display region and a second display region each configured to display an image; an optical device under the first display region of the substrate; a plurality of first pixels in the first display region and a plurality of second pixels in the second display region, each of the first pixels and the second pixels including a first light-emitting element configured to emit a first color light; a plurality of transmissive portions between the first pixels in the first display region; a plurality of driving transistors in the first display region and the second display region and respectively configured to drive the first pixels and the second pixels, the driving transistors including a first driving transistor connected to the first light-emitting element in one of the first pixels and a second driving transistor connected to the first light-emitting element in one of the second pixels; at least one insulating layer between the first driving transistor and the first light-emitting element in the one of the first pixels and between the second driving transistor and the first light-emitting element in the one of the second pixels; and a plurality of contact holes through the at least one insulating layer. More of the contact holes may be disposed between the first driving transistor and the first light-emitting element in the one of the first pixels than between the second driving transistor and the first light-emitting element in the one of the second pixels.

It is to be understood that both the foregoing general description and the following detailed description of the present disclosure are by way of example and are intended to provide further explanation of the disclosures as claimed.

### BRIEF DESCRIPTION OF THE DRAWINGS

The accompanying drawings, which are included to provide a further understanding of the present specification and are incorporated in and constitute a part of this application, illustrate example embodiments of the present specification and together with the description serve to explain various principles of the present specification. In the drawings

FIG. 1 is a plan view of a display panel according to one or more example embodiment of the present specification;

FIG. 2 is a plan view of a first display region and a second display region according to an example embodiment of the present specification;

FIG. 3 is a plan view of a first display region and a second display region according to another example embodiment of the present specification;

FIG. 4 is an enlarged view of a partial region of the second display region in FIG. 2;

FIG. 5A is a set of cross-sectional views taken along lines V-1-V-1′ and V-2-V-2′ in FIG. 4;

FIG. 5B is a cross-sectional view of a transmissive portion in FIGS. 2 and 3;

FIG. 6A is an enlarged view of a partial region of the first display region in FIG. 3;

FIG. 6B is an enlarged view of a partial region of the first display region in FIG. 2;

FIG. 7 is a set of cross-sectional views taken along lines V-3-V-3′, V-4-V-4′, and V-5-V-5′ in FIG. 6A;

FIG. 8 is a cross-sectional view taken along line V-6-V-6′ in FIG. 6B;

FIG. 9A is a plan view of a display panel according to an example embodiment of the present specification;

FIG. 9B is a plan view of a display panel according to another example embodiment of the present specification;

FIG. 10A is an enlarged view of a partial region of a first display region in FIG. 9A;

FIG. 10B is an enlarged view of a partial region of a first display region in FIG. 9B; and

FIG. 11 is a plan view of a display panel according to an example embodiment of the present specification.

### DETAILED DESCRIPTION

Advantages and features of the present specification and a method of achieving the same should become clear with example embodiments described in detail below with reference to the accompanying drawings. However, the present specification is not limited to the example embodiments described below and may be implemented with a variety of different modifications. The example embodiments are provided to allow those skilled in the art to understand the scope of the present specification more fully.

The shapes, dimensions, ratios, angles, numbers, and the like disclosed in the drawings for describing the example embodiments of the present specification are merely illustrative and do not limit the embodiments of the present specification to the illustrated details. Like reference numerals refer to like elements throughout the specification, unless otherwise specified. Further, in describing the present specification, detailed descriptions of well-known technologies may be omitted where such detailed descriptions may unnecessarily obscure a feature or aspect of the present specification.

Such terms as “including,” “having,” and “composed of,” if used herein, are intended to allow other elements to be added unless the terms are used with a more specific term like “only.” Any references to the singular may include the plural, and vice versa, unless expressly stated otherwise.

Components are to be interpreted as including an ordinary error range even if no such margin is explicitly stated.

In the case of a description of a positional relationship, for example, where a positional relationship between two portions is described with a term like “on,” “above,” “under,” or “next to,” one or more portions may be interposed therebetween unless a more specific term, for example, “right,” “directly,” or “near” is used in the expression.

For a description of a temporal relationship, where a temporal relationship is described as “after,” “subsequently to,” “next,” “before,” or the like, a non-consecutive case may be included unless a more specific term like “immediately” or “directly” is used in the expression.

Although terms like “first” and “second” may be used herein to describe various components, the components are not limited by these terms. These terms are used only to refer to one component separately from another. Therefore, a first component described below may be a second component, and vice versa, within the technological scope of the present specification.

Terms such as first, second, A, B, (a), (b), or the like may be used herein when describing components of the present specification. Such terms are used only to refer to a component separately from another component, but do not limit the nature, sequence, order, number, or the like of components.

It is to be understood that where a component is described as being “connected,” “coupled,” “linked,” or “attached” to another component, the component may be directly connected, coupled, linked, or attached to the other component, but also, unless specifically stated otherwise, still another component may be interposed between these two components so that they are indirectly connected, coupled, linked, or attached.

It is also to be understood that where a component or layer is described as being “in contact with” or “overlapping” another component or layer, the component or layer may be in direct contact with or directly overlapping the other component or layer, but also, unless specifically stated otherwise, still another component or layer may be interposed between these two components or layers so that they are in indirect contact with or indirectly overlapping each other.

The term “at least one” should be understood as including any and all combinations of one or more of the associated listed components. For example, the meaning of “at least one of a first component, a second component, and a third component” encompasses all possible combinations of two or more of the first component, the second component, and the third component as well as the first component, the second component, or the third component individually.

Terms like “first direction,” “second direction,” “third direction,” “X-axis direction,” “Y-axis direction,” and “Z-axis direction” should not be interpreted as referring only to geometrical relationships that are perpendicular to each other. Unless otherwise specified, they may indicate a broader range of directions within the functional scope of the configuration described in the present specification.

The features of various embodiments of the present specification may be partially or entirely combined with each other. The embodiments may be technically linked and operate in various ways and may be carried out independently of or in association with each other.

Hereinafter, various example embodiments of the present specification will be described in detail with reference to the accompanying drawings.

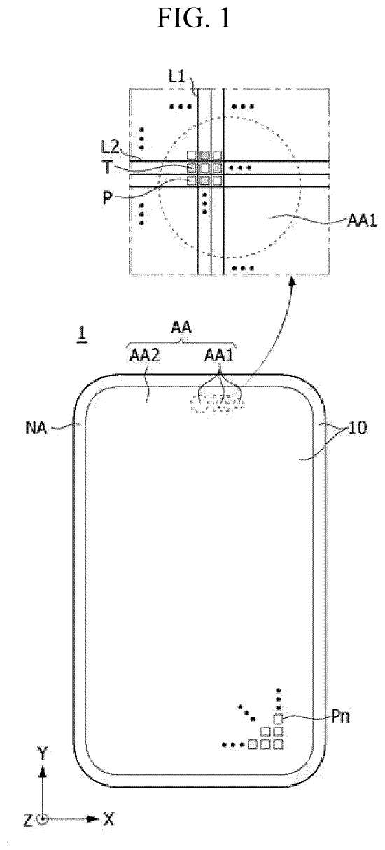

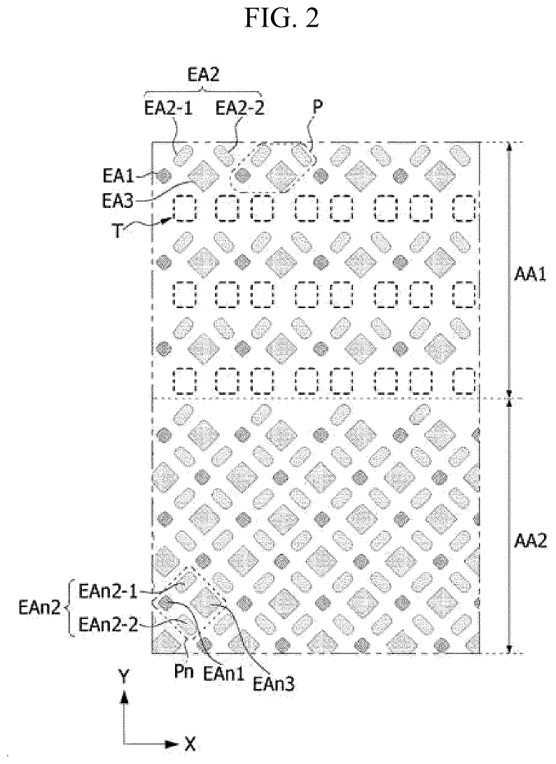

FIG. 1 is a schematic plan view of a display panel according to one or more embodiments of the present specification. FIG. 2 is a schematic plan view of a first display region and a second display region according to an example embodiment of the present specification.

As shown in FIGS. 1 and 2, a display panel 1 according to one or more example embodiments of the present specification may include a substrate 10 including a first display region AA1 including a light-emitting unit EA and a transmissive portion T, and a second display region AA2 surrounding the first display region AA1, and a light-emitting element disposed on the substrate 10 and including a first electrode overlapping the light-emitting unit EA and a second electrode facing the first electrode.

A row direction (X) and a column direction (Y) of the display panel 1 may be a longitudinal direction (a horizontal direction in FIG. 1) and a height direction (a vertical direction in FIG. 1) of the display panel 1, respectively. A thickness direction (Z) may mean a direction perpendicular to a plane having the row direction (X) and the column direction (Y) of the display panel 1. Further, the display panel 1 may have a cross-section in the thickness direction.

The substrate 10 may include a display region AA and a non-display region NA around the display region AA. The display region AA may be a region where an image appears, and the non-display region NA may be a region where the image does not appear.

The display region AA may include the first display region AA1 and the second display region AA2 surrounding the first display region AA1. Since an image is displayed in both the first display region AA1 and the second display region AA2, a plurality of pixel units P and Pn may be disposed. Here, the first display region AA1 may further include transmissive portions T disposed between the pixel units P.

In some cases, a plurality of first pixel units P disposed in the first display region AA1 and a plurality of second pixel units Pn disposed in the second display region AA2 may have different alignment structures. Further, structures of light-emitting units EA and EAn respectively in the first and second pixel units P and Pn may be different from each other.

A plurality of first display regions AA1 may be configured. Each of the plurality of first display regions AA1 may include an optical electronic device. The optical electronic device may include a light-receiving device which receives light, such as a camera or sensor. However, the display panel 1 of the present specification is not limited thereto. For example, one of the first display region AA1 may be an under display camera (UDC) region with a built-in camera, and another may be an under display infrared radiation (UDIR) region with a built-in infrared (IR) sensor. In the one or more example embodiments according to the present specification, as illustrated in FIG. 1, the first display region AA1 is shown as being disposed in an upper center region, but embodiments of the present specification are not limited thereto. For example, the first display region AA1 may be disposed in an upper left region or an upper right region. The display panel 1 according to one or more embodiments of the present specification may include a plurality of signal lines L1 and L2 formed across the first and second display regions AA1 and AA2. The plurality of signal lines L1 and L2 may include lines for transmitting signals to a camera or sensor and the first pixel units P disposed in the first display region AA1.

At least one signal line L1 formed in the column direction (Y) may be disposed between the first pixel units P or between the transmissive portions T disposed in the row direction (X). For example, the signal lines L1 formed in the column direction (Y) may include various signal lines such as a signal line, a data line or gate line, and a power voltage line connected to a camera or sensor.

At least one signal line L2 formed in the row direction (X) may be disposed between the transmissive portions T adjacent to each other in the column direction (Y). For example, the signal lines L2 formed in the row direction (X) may include various signal lines such as a signal line, a data line or gate line, and a power voltage line connected to a camera or sensor.

A part of the signal line L2 formed in the row direction (X) may be disposed to overlap the first pixel unit P. Where the first pixel units P are repeatedly disposed in the row direction (X) and the transmissive portion T is disposed between the first pixel units P adjacent to each other in the column direction (Y), a signal line L2 formed in the row direction (X) may be disposed across the first pixel unit P. This will be described below in more detail in the following description of example embodiments.

In the first display region AA1, the plurality of first pixel units P and the plurality of transmissive portions T may be repeatedly disposed. As illustrated in FIG. 2, the plurality of first pixel units P disposed in the first display region AA1 may be disposed in parallel in the row direction (X) and the column direction (Y), and may be disposed with a wider separation distance in the column direction (Y) than in the row direction (X). In this case, the transmissive portions T may be disposed between the first pixel units P disposed in the first display region AA1 and adjacent to each other in the column direction (Y).

The plurality of transmissive portions T may be disposed spaced apart from each other between the first pixel units P adjacent to each other in the column direction (Y). For example, for any first row and second row of first pixel units P that are located adjacent to each other, a row of transmissive portions T may be disposed in parallel in the row direction (X) between the first pixel units P disposed in the first row and the first pixel units P disposed with the second row.

The plurality of transmissive portions T may be disposed spaced apart from each other in the row direction (X) with at least one signal line (L1 in FIG. 1) therebetween. In other words, at least one signal line L1 may be disposed in a boundary region, which is a region between the transmissive portions T adjacent to each other in the row direction (X). In the following example embodiments, an example in which at least one data line DL is disposed between the transmissive portions T adjacent to each other is described, but the present specification is not limited thereto.

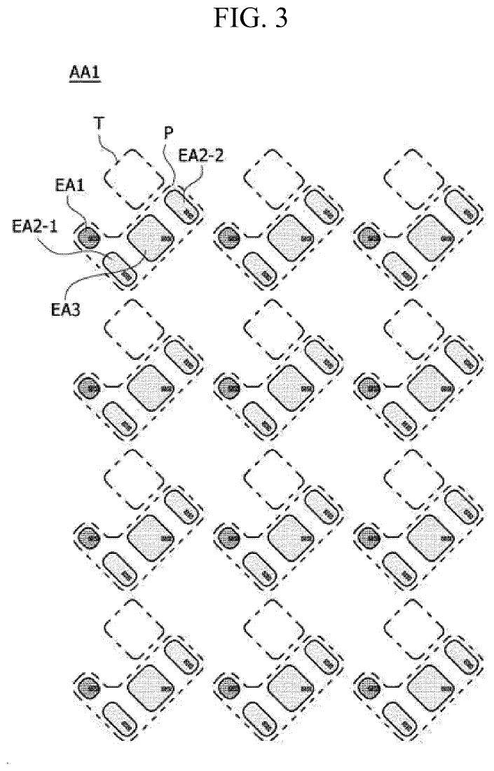

In the structure between the first display region AA1 and the second display region AA2, the structure of the first display region AA1 is not limited to those illustrated in FIGS. 1 and 2. For example, the first display region AA1 is not limited to that shown in FIGS. 1 and 2 and may instead have a structure of the plurality of pixel units P and the plurality of transmissive portions T as shown in FIG. 3. An arrangement structure of the plurality of pixel units P and the plurality of transmissive portions T will be described in detail in the following example embodiments.

The second display region AA2 may be a regular (or normal) display region which occupies nearly the entire portion of the image or an overall portion of the image outside the first display region AA1. The plurality of second pixel units Pn may be repeatedly disposed in the second display region AA2. The number of second pixel units Pn per unit area disposed in the second display region AA2 may be greater than the number of first pixel units P per unit area disposed in the first display region AA1.

The plurality of second pixel units Pn may form an alignment structure in which the second pixel units Pn are disposed in the row direction (X), the column direction (Y), and a diagonal direction (for example, an X=Y axis direction) for each second pixel unit Pn. However, the alignment structure of the plurality of second pixel units Pn of the display panel 1 of the present specification is not limited to that of an example shown in FIG. 2. For example, the plurality of second pixel units Pn may be arranged in a matrix-type grid structure intersecting each other.

The first and second pixel units P and Pn may be unit pixels including the light-emitting units EA and EAn of different colors, respectively. The first and second pixel units P and Pn may be formed of the light-emitting units EA and EAn in a region where light is actually emitted and non-light-emitting units in a region where light is not emitted around the light-emitting units EA and EAn, respectively. Each of the light-emitting units EA and EAn may be defined by a gate line GL and a data line DL formed in a matrix form by intersecting each other on the substrate 10.

An arrangement structure of the light-emitting units EA of the first pixel unit P and an arrangement structure of the light-emitting units EAn of the second pixel unit Pn may be different from each other.

In common, the first and second pixel units P and Pn may respectively include first and first (regular or normal) light-emitting units EA1 and EAn1, second and second (regular or normal) light-emitting units EA2 and EAn2, and third and third (regular or normal) light-emitting units EA3 and EAn3 of different colors. However, the display panel 1 of the present specification is not limited thereto. For example, to overcome or compensate for a difference in resolution between the first display region AA1 and the second display region AA2, each of the first and second pixel units P and Pn may include light-emitting units which emit different colors. In the present specification, an example of having light-emitting units EA and EAn of the same color to more clearly show a difference between the first and second pixel units P and Pn is described.

The first and first (regular or normal) light-emitting units EA1 and EAn1 may emit red light, the second and second (regular or normal) light-emitting units EA2 and EAn2 may emit green light, and the third and third (regular or normal) light-emitting units EA3 and EAn3 may emit blue light. Here, the second and second (regular or normal) light-emitting units EA2 and EAn2 may include 2-1 and 2-2 light-emitting units EA2-1 and EA2-2, and 2-1 (normal or regular) and 2-2 (normal or regular) light-emitting units EnA2-1 and EAn2-2, respectively.

Thus, the display panel 1 according to an example embodiment of the present specification may have a pentile pixel structure of RGBG (red, green, blue, and green subpixels). In the pentile pixel structure, more light-emitting units of a specific color may be disposed unlike a general RGB (red, green, and blue subpixels) array structure. The pentile pixel structure may increase the clarity and resolution of the image while reducing the number of pixels.

For example, in the case of an RGBG array structure, more G (green) subpixels are disposed. G (green) may be visually most sensitively reacted to compared to other colors. Accordingly, the more G (green) subpixels are disposed, the more a visually sharp image may be felt.

Further, each of the two G (green) subpixels may compensate for R (red) and B (blue) subpixels. Each of the two G (green) subpixels may appropriately reinforce signals of the R (red) and B (blue) subpixels to naturally express the color of the pixel unit. In addition, neighboring pixel information may be used to compensate for an insufficient portion of the pixel unit to make the resolution appear high.

In the display panel 1 according to one or more embodiments of the present specification, since the transmissive portions T are disposed in the first display region AA1, the first display region AA1 may have a relatively lower resolution compared to the second display region AA2. Accordingly, the display panel 1 of according to one or more embodiments the present specification may apply the pentile pixel structure to the first display region AA1 and the second display region AA2. Accordingly, the display panel 1 according to one or more embodiments of the present specification may increase the clarity of the first display region AA1 to adjust the resolution of the first display region AA1 to the same or substantially same level as the resolution of the second display region AA2.

However, the display panel 1 of the present specification is not limited thereto. For example, the first and second pixel units P and Pn may further include white light-emitting units or may form another pentile pixel structure to improve emission efficiency. Hereinafter, in the present specification, an example in which the first to third light-emitting units EA1 and EAn1, EA2 and EAn2, and EA3 and EAn3 that have the pentile pixel structure will be described.

In the first pixel unit P, as illustrated in FIG. 2, the first light-emitting unit EA1 and the third light-emitting unit EA3 may be disposed in parallel in the row direction (X). The second light-emitting unit EA2 may be disposed at one side of the first light-emitting unit EA1 and the third light-emitting unit EA3 in the column direction (Y). In this case, the second light-emitting unit EA2 may be branched into the 2-1 light-emitting unit EA2-1 and the 2-2 light-emitting unit EA2-2.

The second light-emitting unit EA2 included in the first pixel unit P may include the 2-1 light-emitting unit EA2-1 and the 2-2 light-emitting unit EA2-2. The 2-1 light-emitting unit EA2-1 and the 2-2 light-emitting unit EA2-2 according to an example embodiment may be disposed along the row direction (X) in parallel with the direction along which the first light-emitting unit EA1 and the third light-emitting unit EA3 are arranged and may be disposed at one side of the first light-emitting unit EA1 and the third light-emitting unit EA3 in the column direction (Y). Accordingly, an area occupied by a configuration which connects the 2-1 light-emitting unit EA2-1 and the 2-2 light-emitting unit EA2-2 may be relatively reduced.

In the second pixel unit Pn, as shown in FIG. 2, the first (regular or normal) light-emitting unit EAn1 and the third (regular or normal) light-emitting unit EAn3 may be arranged along the row direction (X). The second (regular or normal) light-emitting unit EAn2 may be branched into a 2-1 (regular or normal) (or 2-1n) light-emitting unit EAn2-1 and a 2-2 (regular or normal) or (2-2n) light-emitting unit EAn2-2, which may be disposed along the column direction (Y) intersecting the row direction (X) along which the first (regular or normal) and third (regular or normal) light-emitting units EAn1 and EAn3 are arranged.

FIG. 3 is a cross-sectional view of a display device according to another example embodiment of the present specification.

As shown in FIG. 3, a first pixel unit P of a first display region AA1 according to another example embodiment of the present specification may include a first light-emitting unit EA1, a second light-emitting unit EA2, and a third light-emitting unit EA3. The second light-emitting unit EA2 may be branched into a 2-1 light-emitting unit EA2-1 and a 2-2 light-emitting unit EA2-2. The first light-emitting unit EA1 and the third light-emitting unit EA3 may be disposed along the row direction (X). The 2-1 light-emitting unit EA2-1 and the 2-2 light-emitting unit EA2-2 may be disposed along a diagonal line between the row direction (X) the column direction (Y) with the third light-emitting unit EA3 interposed therebetween. The third light-emitting unit EA3 may be disposed between the 2-1 light-emitting unit EA2-1 and the 2-2 light-emitting unit EA2-2 along this diagonal line between the row direction (X) and the column direction (Y).

A transmissive portion T may be disposed between the first pixel units P. In more detail, the transmissive portion T may be disposed along the diagonal line between the row direction (X) and the column direction (Y) from the first light-emitting unit EA1, and may be disposed adjacent to the 2-2 light-emitting unit EA2-2 in the row direction (X) and/or adjacent to the third light-emitting unit EA3 in the column direction (Y).

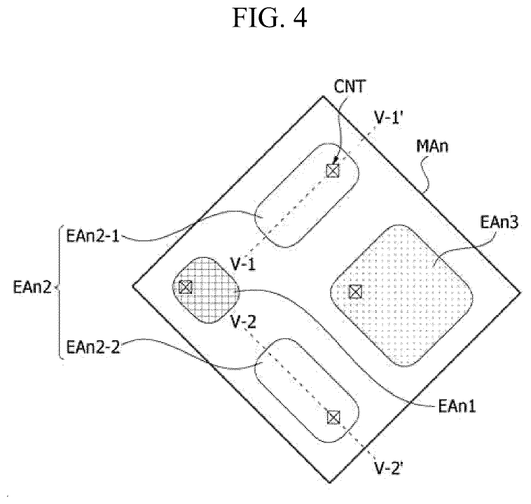

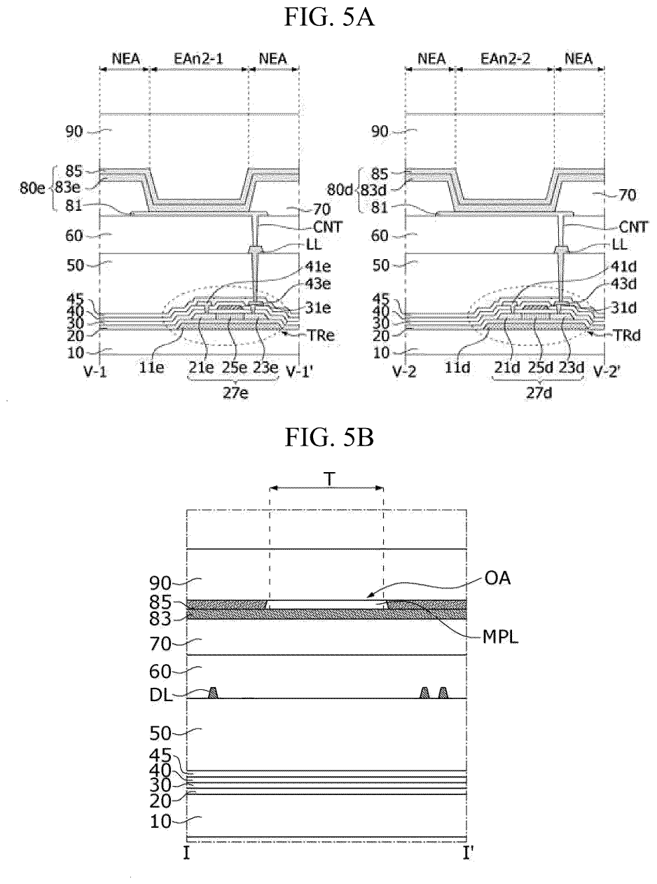

FIG. 4 is an enlarged view of a partial region of the second display region in FIG. 2. FIG. 5A is a set of cross-sectional views taken respectively along lines V-1-V-1′ and V-2-V-2′ in FIG. 4. FIG. 5B is a cross-sectional view of the transmissive portion in FIGS. 2 and 3.

As shown in FIG. 4 and FIG. 5A, the 2-1n (or 2-1 (regular or normal)) light-emitting unit EAn2-1 and the 2-2n (or 2-2 (regular or normal)) light-emitting unit EAn2-2 of the second pixel unit Pn may be independently driven. Accordingly, in the second display region AA2, the clarity and resolution of an image may be increased while reducing the number of pixels from a pentile pixel structure.

As illustrated in FIG. 4, the second display region AA2 may include a second driving circuit unit MAn overlapping the second pixel unit Pn. The second driving circuit unit MAn may be a region where circuits for driving light-emitting elements forming the light-emitting units EAn are disposed. The second driving circuit unit MAn may apply a driving signal to the light-emitting elements disposed in the second pixel unit Pn. However, the display panel 1 of the present specification may not be limited to the region of the second driving circuit unit Man shown in FIG. 4. For example, the second driving circuit unit MAn may include a region smaller than or equal to a region of the second pixel unit Pn.

As shown in FIG. 5A, the 2-1n light-emitting unit EAn2-1 and the 2-2n light-emitting unit EAn2-2 of the second pixel unit Pn may be regions where light is emitted based on outputs from different transistors Tre and TRd. However, the transistors Tre and TRd of the present specification are not limited to the example shown in FIG. 5A. In the present specification, for convenience of description, one transistor TRe or TRd corresponding to each of the 2-1n light-emitting unit EAn2-1 and the 2-2n light-emitting unit EAn2-2 is shown.

A contact hole CNT for connecting each transistor TRe or TRd to a first electrode 81 of the light-emitting element may be disposed when one transistor Tre or TRd corresponding to each of the 2-1n light-emitting unit EAn2-1 and the 2-2n light-emitting unit EAn2-2 is provided.

As illustrated in FIG. 5A, a buffer film 20, a gate insulating film 30, an interlayer insulating film 40, a passivation layer 45, a first planarization layer 50, a second planarization layer 60, a bank 70, and a light-emitting element 80 may be sequentially formed between the substrate 10 and an encapsulation film 90 disposed in the second display region AA1 of the display panel 1 according to an example embodiment of the present specification.

More specifically, the buffer film 20 may be disposed on the substrate 10. The buffer film 20 may be formed in a single layer structure or a multilayer structure of silicon oxide (SiOₓ) and/or silicon nitride (SiNₓ). A light blocking layer 11 (e.g., 11a, 11b, 11c, 11d, and/or 11e) may be disposed between the substrate 10 on which the transistor TR (e.g., TRa, TRb, TRc, TRd, and/or TRe) is disposed and the buffer film 20. The light blocking layer 11 may overlap a channel region 25 (e.g., 25a, 25b, 25c, 25d, and/or 25e) of at least an active layer 27 (e.g., 27a, 27b, 27c, 27d, and/or 27e) of the transistor TR (e.g., TRa, TRb, TRc, TRd, and/or TRe), and may be disposed under the active layer 27. The light blocking layer 11 may prevent or block external light from passing through the first substrate 10 and being transmitted to the transistor TR.

For example, the light blocking layer 11 may be made of a single layer of a metal material, such as molybdenum (Mo), titanium (Ti), aluminum-neodymium (AlNd), aluminum (Al), chromium (Cr), or an alloy thereof, or may be formed in a multilayer structure using one or more of such metal materials. The buffer film 20 on the light blocking layer 11 may cover the light blocking layer 11.

The gate insulating film 30 and the interlayer insulating film 40 disposed sequentially on the buffer film 20 may include a contact hole which exposes each of a source region 21 (e.g., 21a, 21b, 21c, 21d, and/or 21e) and a drain region 23 (e.g., 23a, 23b, 23c, 23d, and/or 23e) of the active layer 27. The gate insulating film 30 may insulate a gate electrode 31 (e.g., 31a, 31b, 31c, 31d, and/or 31e) from the channel region 25 of the active layer 27, and the interlayer insulating film 40 may cover the gate electrode 31. For example, the gate insulating film 30 and the interlayer insulating film 40 may each be made of an inorganic insulating material. In this case, each of the gate insulating film 30 and the interlayer insulating film 40 may be made of a single layer or multiple layers of a silicon oxide film (SiOₓ), a silicon nitride film (SiNₓ), and/or a silicon oxynitride film (SiOₓN_{y}).

The source electrode 41 (e.g., 41a, 41b, 41c, 41d, and/or 41e) and the drain electrode 4 (e.g., 43a, 43b, 43c, 43d, and/or 43e) may be disposed on the same layer, e.g., on the interlayer insulating film 40 as in this example. The source electrodes 41 and the drain electrodes 43 are connected to the source region 21 and the drain region 23 of the active layer 27 through contact holes, respectively.

For example, each of the source electrode 41 and the drain electrode 43 may be made of a single layer of a metal material, such as molybdenum (Mo), aluminum (Al), chromium (Cr), gold (Au), titanium (Ti), nickel (Ni), neodymium (Nd), copper (Cu), or an alloy thereof, or may be formed in a multilayer structure using one or more of such metal materials.

The passivation layer 45 on the interlayer insulating film 40 may cover the transistor TR. Accordingly, the transistor TR may be protected by the passivation layer 45. For example, the passivation layer 45 may be a type of inorganic insulating film and may be made of a single layer or multiple layers of a silicon oxide film (SiOₓ), a silicon nitride film (SiNₓ), and/or a silicon oxynitride film (SiOₓNₓ).

At least one planarization layer may be disposed on the passivation layer 45. At least one planarization layer may include first and second planarization layers 50 and 60 sequentially disposed on the passivation layer 45.

The first planarization layer 50 may be formed with a thickness capable of sufficiently planarizing a surface step of an upper portion of the transistor TR and may be formed of an organic insulating film. However, the present specification is not limited thereto. For example, where the first planarization layer 50 also functions to protect the transistor TR, the passivation layer 45 may be omitted.

For example, the first planarization layer 50 may be a type of organic insulating film, may be made of any one of photo acryl, polyimide, a benzocyclobutene series resin, and the acrylate series, and in some cases, may be formed of multiple layers.

A connection electrode LL may be disposed on the first planarization layer 50. Also, the connection electrode LL may be disposed in a contact hole through the first planarization layer 50. The connection electrode LL may be formed along with a signal line SL (or a data line DL) on the first planarization layer 50. The connection electrode LL may electrically connect the first electrode 81 of a light-emitting element 80 (e.g., 80a, 80b, or 80c) and the transistor TR through the contact hole CNT.

For example, the connection electrode LL may be made of a single layer of a metal material, such as molybdenum (Mo), aluminum (Al), chromium (Cr), gold (Au), titanium (Ti), nickel (Ni), neodymium (Nd), copper (Cu), or an alloy thereof, or may be formed in a multilayer structure using one or more of such metal materials.

The second planarization layer 60 may be disposed on the first planarization layer 50. The second planarization layer 60 may cover various circuits or the signal lines SL and the connection electrodes LL disposed on the first planarization layer 50. The second planarization layer 60 may be a type of organic insulating film and may be made of any one of photo acryl, polyimide, a benzocyclobutene series resin, and the acrylate series.

The light-emitting element 80 (e.g., 80a, 80b, 80c, 80d, and/or 80e) may be disposed on the second planarization layer 60. When current supplied from a power voltage line flows to a second electrode 85 and a high-voltage current is supplied to the first electrode 81 from the corresponding transistor TR, the light-emitting element 80 may be driven so that light is emitted from an intermediate layer 83 (83a, 83b, 83c, 83d, and/or 83e) while an electric field is formed between the first electrode 81 and the second electrode 85.

In this case, the light-emitting units EA1, EA2, and EA3, which are regions where light is emitted from the light-emitting elements 80, may be regions exposed from the bank 70, but the display panel of the present specification is not limited thereto. For example, the light-emitting unit may include a side surface and an upper surface of the bank 70 where the intermediate layer 83 may be provided.

The first electrode 81 may be provided in each of the subpixels and may be electrically connected to a corresponding one of the transistors TR. Where the display panel of an example embodiment of the present specification is a top emission type, the first electrode 81 may be formed to have higher reflection efficiency than the second electrode 85 so as to reflect light generated from the intermediate layer 83.

For example, the first electrode 81 may be formed in a multilayer structure including a transparent conductive film and an opaque conductive film with high reflection efficiency. The transparent conductive film of the first electrode 81 may be made of a material having a relatively high work function value, such as indium tin oxide (ITO) or indium zinc oxide (IZO), and the opaque conductive film of the first electrode 81 may be made of a single layer or multiple layers of any one selected from the group consisting of silver (Ag), aluminum (Al), copper (Cu), molybdenum (Mo), titanium (Ti), nickel (Ni), chromium (Cr), or tungsten (W), or an alloy thereof.

For example, the first electrode 81 may be formed in a structure in which a transparent conductive film, an opaque conductive film, and a transparent conductive film are sequentially stacked, or in a structure in which a transparent conductive film and an opaque conductive film are sequentially stacked.

The intermediate layer 83 on the first electrode 81 may be provided over the entire first and second display regions AA1 and AA2. Specifically, the intermediate layer 83 may be provided on the first electrode 81 opened by the bank 70, and a side surface and an upper surface of the bank 70.

The intermediate layer 83 may include, for example, a single stack of organic layers formed of multiple layers including a hole injection layer HIL, a hole transport layer HTL, an emission layer EML, an electron transport layer ETL, and an electron injection layer EIL. In some cases, the intermediate layer 83 may have a tandem structure including multiple stacks (e.g., a first stack and a second stack) each including a light-emitting layer and a charge generation layer CGL between the stacks. Further, the tandem structure of the intermediate layer 83 is not limited to a two-stack structure and may be formed of three or more stacks.

In the plurality of stacks, each of the light-emitting layers may be a light-emitting layer of the same color which emits light of any one of red, green, and blue colors, and may be disposed to overlap each of the light-emitting units EA1, EA2, and EA3. A plurality of layers of the intermediate layer 83 excluding the light-emitting layer may be provided on the entire surface of the substrate 10 with a common mask. Alternatively, when white light is emitted through a plurality of light-emitting layers in a multiple stack structure of 2 stacks or more, each of the light-emitting layers may be provided on the entire surface of the substrate 10 with a common mask like other intermediate layers 83. Here, the charge generation layer may be formed of a double layer of an n-type and a p-type. The n-type charge generation layer and the p-type charge generation layer of the charge generation layer may include an n-type dopant and a p-type dopant, respectively.

The second electrode 85 on the intermediate layer 83 may be disposed to face the first electrode 81 in the display regions AA1 and AA2. In some cases, the second electrode 85 may also be disposed in the non-display region NA to be in contact with a circuit unit in the non-display region NA.

The second electrode 85 may include an opening. The opening may completely overlap the transmissive portion T of the substrate 10. The opening may not overlap patterned configurations such as a first driving circuit unit MA, the data line DL, the gate line GL, and the signal line SL.

Light entering from the outside of the display panel 1 may move from a place with a low refractive index to a place with a high refractive index based on the second electrode 85. For example, light may move from the encapsulation film 90 to the second electrode 85. Most of the light may be reflected when moving to the second electrode 85 with a relatively high refractive index. Only some of the light transmitted through the second electrode 85 may be diffracted by components of the first driving circuit unit MA.

Accordingly, in the display panel 1 according to one or more example embodiments of the present specification, as the first driving circuit unit MA overlaps the second electrode 85 without being disposed in the transmissive portion T, diffraction may be minimized or reduced. Accordingly, the display panel 1 according to one or more example embodiments of the present specification may improve a point spread function (PSF) by preventing or suppressing the intensity of light from being reduced at a peak wavelength of the PSF.

Where the display panel of the present specification is a top emission type, the second electrode 85 may be made of a conductive layer of a transparent material. For example, the second electrode 85 may be made of a transparent conductive material, such as indium tin oxide (ITO) or indium zinc oxide (IZO).

As shown in FIG. 5B, a metal patterning layer MPL may be disposed on the intermediate layer 83, i.e., on the same layer as the second electrode 85. The metal patterning layer MPL may be disposed to form an opening OA in the second electrode 85. Accordingly, the metal patterning layer MPL may include the transmissive portion T therein. However, the present specification is not limited to this example of configuring the metal patterning layer MPL as a configuration for patterning the second electrode 85. For example, the second electrode 85 may be patterned through a mask process without configuring the metal patterning layer MPL. Hereinafter, in the following example embodiments, an example in which the metal patterning layer MPL is used to configure the opening OA in the second electrode 85 will be described.

The metal patterning layer MPL may have a surface having low affinity for the conductive material and thus may have a surface in which deposition of the second electrode 85 of the conductive material is suppressed. To this end, the metal patterning layer MPL may include a material having the following characteristics.

The metal patterning layer MPL may include a polycyclic aromatic compound including an organic molecule including at least one of heteroatoms, such as nitrogen (N), sulfur (S), oxygen (O), phosphorus (P), aluminum (Al), and the like, as an organic material including an organic material and an organic polymer. The polycyclic aromatic compound may include an organic molecule including a core moiety and at least one terminal moiety combined with the core moiety.

For example, the metal patterning layer MPL material may include 3-(4-biphenyl)-4-phenyl-5-tert-butylphenyl-1,2,4-triazole (TAZ), aluminum(III)bis(2-methyl-8-quinolinato)-4-phenylphenolate(BA1q), 2-(4-(9,10-di(naphthalen-2-yl)anthracen-2-yl)phenyl)-1-phenyl-1H-benzo-[D]imidazole, 8-hydroxyquinoline lithium (Liq), N(diphenyl-4-yl)9, 9-dimethyl-N-(4(9-phenyl-9H-carbazol-3-yl)phenyl)-9H-fluoren-2-amine, and the like.

When the material for the second electrode 85 is deposited on the surface of the metal patterning layer MPL, the material may not stick to the surface of the metal patterning layer MPL due to its low affinity for the metal patterning layer MPL. In other words, the second electrode 85 may have a very low surface sticking probability for the metal patterning layer MPL.

Here, the surface sticking probability may be measured from depositing an amount of a conductive material required to form a closed-packed layer having an average thickness of 1 nm on the surface of the metal patterning layer MPL. Specifically, as a conductive material is simultaneously deposited on the surface of the metal patterning layer MPL and on the substrate, when the average thickness of the closed-packed layer on the surface of the metal patterning layer MPL reaches 1 nm, the surface sticking probability of the conductive material to the metal patterning layer MPL may be derived by comparing the average thickness of the conductive material deposited on the substrate.

The deposition of the second electrode 85 may stick to the surface of the metal patterning layer MPL through a nucleation and growth process with the surface of the metal patterning layer MPL. However, as described above, the second electrode 85 of the conductive material may have a low sticking probability to the metal patterning layer MPL. The surface sticking probability of the conductive material to the metal patterning layer MPL may be as high as 0.3 (or 30%) and as low as 0.0008 (or 0.08%) or less.

Accordingly, during the nucleation and growth process, the conductive materials constituting the second electrode 85 may be detached due to the low affinity to the metal patterning layer MPL. As a result, the second electrode 85 may not be formed on the metal patterning layer MPL.

Since the metal patterning layer MPL is made of an organic material, the transmittance in the transmission portion T may not be reduced due to the above. Accordingly, the display panel according to one or more example embodiments of the present specification may pattern the second electrode 85 through the metal patterning layer MPL without reducing the transmittance of the transmissive portion T.

In another aspect, the bank 70 may cover an edge of the first electrode 81 and may be disposed on the second planarization layer 60. The bank 70 may include an opening which exposes the first electrode 81 as a region for defining the light-emitting unit EA. For example, the bank 70 may be made of an organic material, such as a polyimide, acrylate, a benzocyclobutene series resin, or the like.

The encapsulation film 90 may be disposed on the bank 70 and the second electrode 85. The encapsulation film 90 may be formed of a plurality of layers. For example, the encapsulation film 90 may be formed in a structure in which inorganic films and organic films are alternately stacked. The inorganic film may be composed of a metal oxide, a metal nitride, a metal carbide, and/or a compound thereof. For example, the inorganic film may include inorganic materials, such as AlOₓ, TiO₂, ZrO, SiOₓ, AlON, AlN, SiNₓ, SiOₓN_{y}, InOₓ, YbOₓ, and the like. The organic film may include a polymer-based material. The polymer-based material may include an acrylic resin, an epoxy resin, a silicone resin, polyimide, polyethylene, or the like. In the following example embodiments, the description of the same configuration as in the above example embodiment may be omitted.

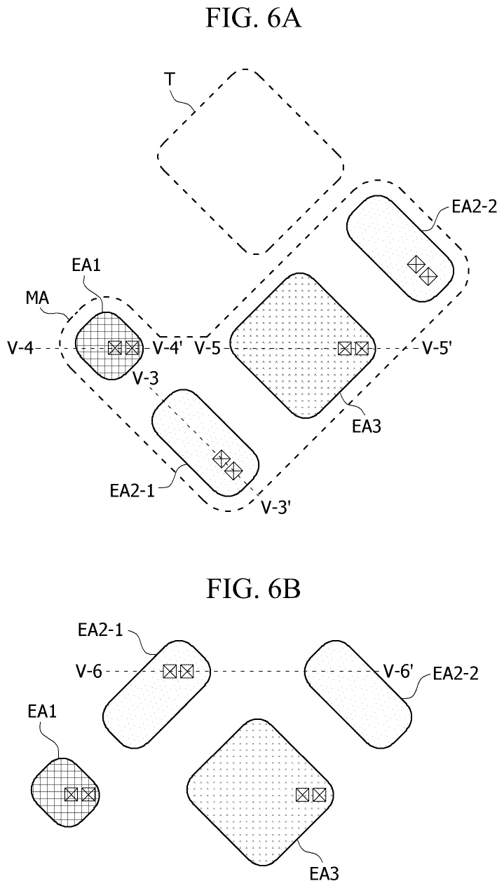

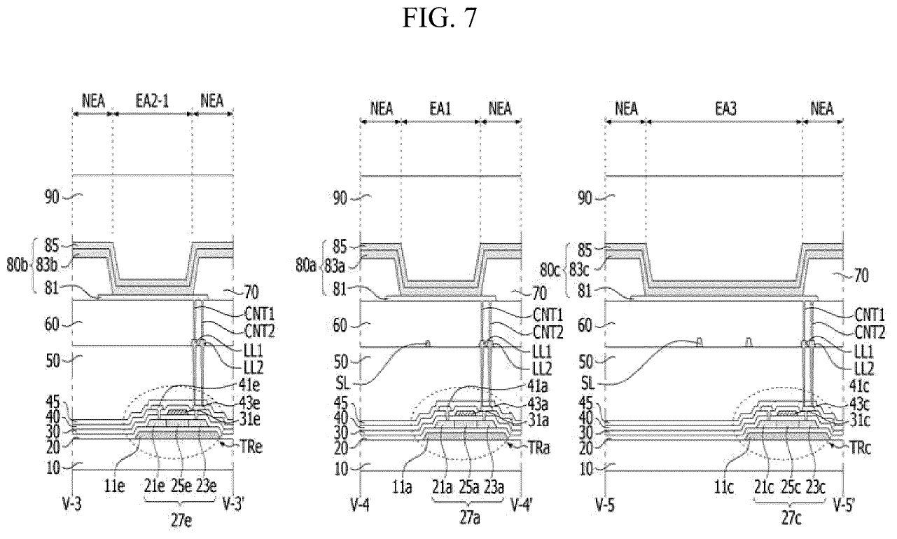

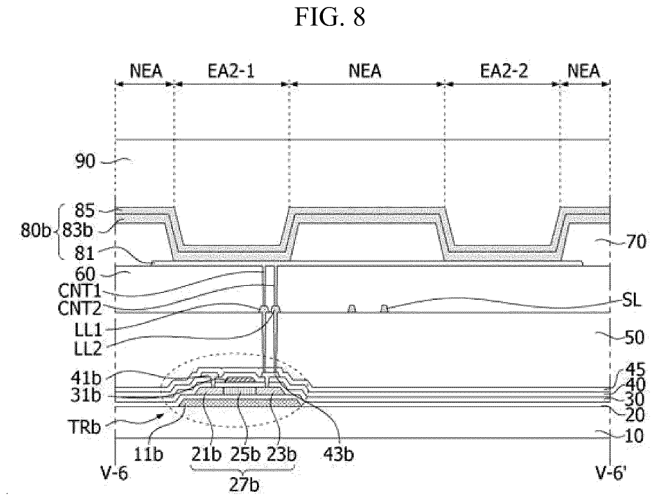

FIG. 6A is an enlarged view of a portion of the first display region AA1 in FIG. 3. FIG. 6B is an enlarged view of a portion of the first display region AA1 in FIG. 2. FIG. 7 is a set of cross-sectional views taken along lines V-3-V-3′, V-4-V-4′, and V-5-V-5′ in FIG. 6A. FIG. 8 is a cross-sectional view taken along line V-6-V-6′ in FIG. 6B.

As illustrated in FIGS. 6A to 8, the contact holes CNT in the first display region AA1 according to example embodiments of the present specification may be disposed between one of the light-emitting units EA1, EA2, and EA3 and the corresponding transistor TR disposed in a first driving circuit unit MA1 disposed under the light-emitting units EA1, EA2, and EA3 and may include a plurality of contact holes CNT1 and CNT2.

The display panel 1 according to example embodiments of the present specification may include fewer transistors in the first driving circuit unit MA1 than in a second driving circuit unit MAn. That is, since the number of transistors TR disposed per unit area in the first display region AA1 is smaller than that in the second display region AA2, the number of contact holes CNT that physically connect the transistors TRs and the first electrodes 81 of the corresponding first light-emitting units EA1, EA2, and EA3 is reduced. Where fewer contact holes CNT are disposed in the first display region AA1 than in the second display region AA2, such element characteristics as a threshold voltage Vth of the transistor TR is affected during such process as a heat treatment process. As a result, a potential problem may appear in which a difference in brightness occurs between the second display region AA2 and the first display region AA1.

As the plurality of contact holes CNT1 and CNT2 are disposed in the first display region AA1 according to example embodiments of the present specification, the number of contact holes CNT disposed in the first display region AA1 increases. Thus, the potential problem of the difference in brightness between the first display region AA1 and the second display region AA2 may be mitigated by uniformly adjusting such element characteristics as the threshold voltage Vth of the transistor TR during such process as a heat treatment process between the first display region AA1 and the second display region AA2.

As shown in FIG. 8, the 2-1 light-emitting unit EA2-1 and the 2-2 light-emitting unit EA2-2 disposed in the first display region AA1 may be simultaneously driven to minimize or reduce the patterned configuration disposed in the first driving circuit unit MA. In this regard, a connection pattern may be disposed to simultaneously drive the 2-1 light-emitting unit EA2-1 and the 2-2 light-emitting unit EA2-2.

The connection pattern may be a configuration which connects the 2-1 light-emitting unit EA2-1 and the 2-2 light-emitting unit EA2-2. For example, the connection pattern may be a configuration of the first electrodes 81 constituting the 2-1 and 2-2 light-emitting elements EA2-1 and EA2-2. For example, the 2-1 and 2-2 light-emitting elements EA2-1 and EA2-2 may have a configuration in which they share the first electrode 81. That is, the shared first electrode 81 is disposed in both the 2-1 and 2-2 light-emitting elements EA2-1 and EA2-2.

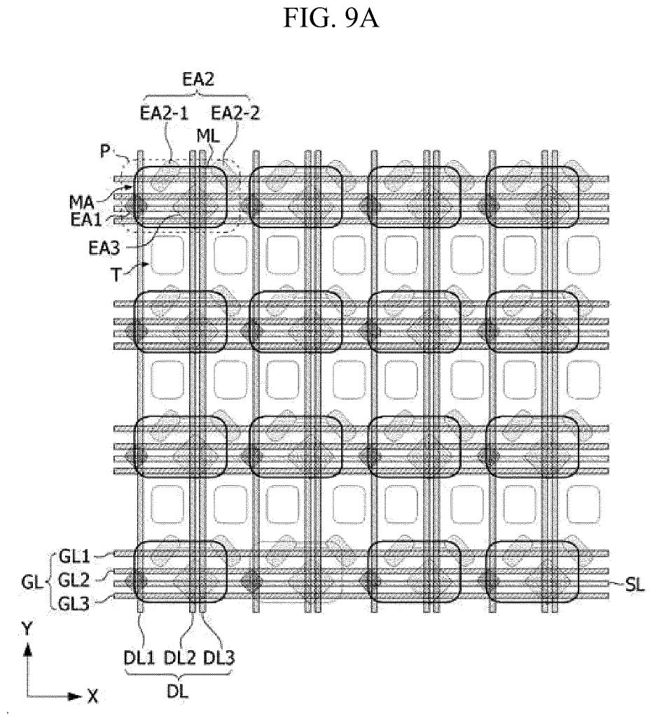

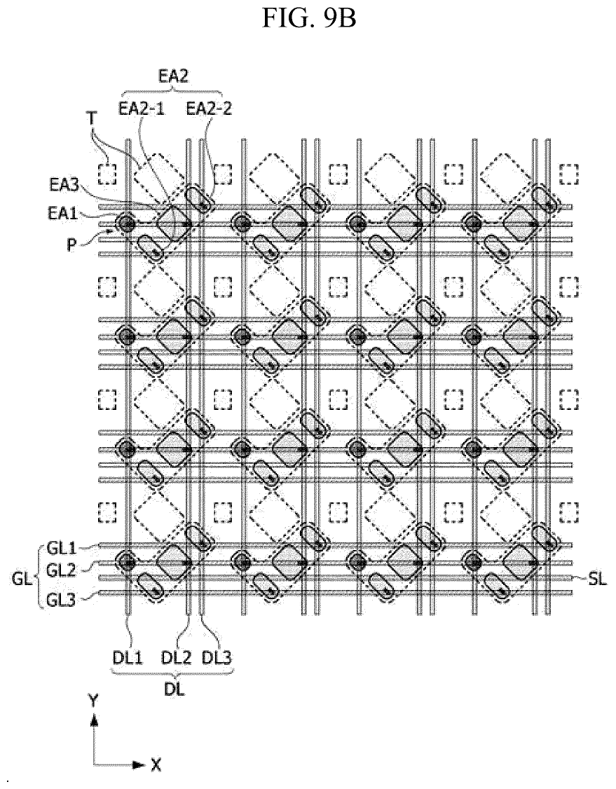

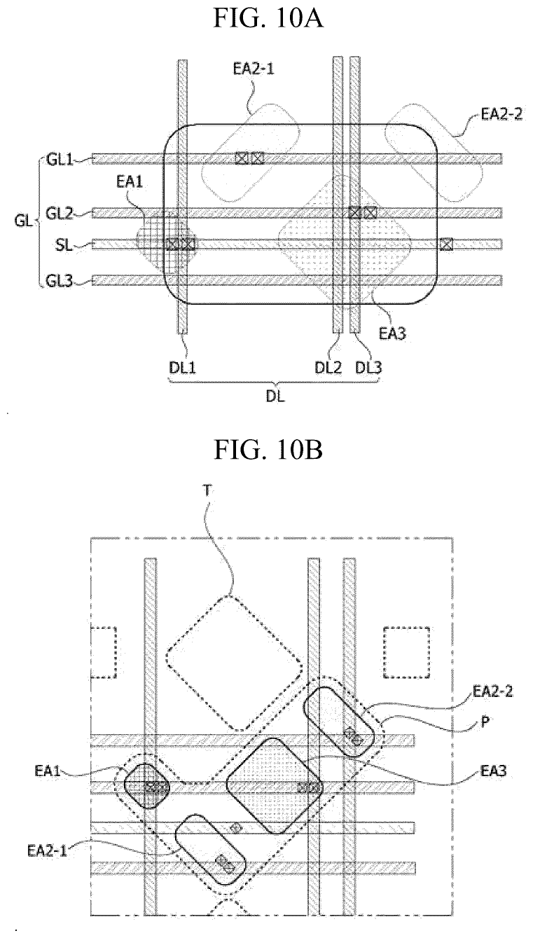

FIG. 9A is a plan view of a first display region AA1 of a display panel according to an example embodiment of the present specification. FIG. 9B is a plan view of a first display region AA1 of a display panel according to another example embodiment of the present specification. FIG. 10A is an enlarged view of a partial region of a first display region AA1 in FIG. 9A. FIG. 10B is an enlarged view of a partial region of a first display region AA1 in FIG. 9B.

As shown in FIGS. 6B, 9A, and 10A, a plurality of first pixel units P may be disposed in parallel along the row direction (X). Further, the rows of first pixel units P may be spaced apart from each other in the column direction (Y) with a row of transmission portions T therebetween. In this case, a separation distance between adjacent first pixel units P in the column direction (Y) may be greater than a separation distance between adjacent first pixel units P in the row direction (X).

The first display region AA1 may include a plurality of first pixel units P and a plurality of transmissive portions T. Further, various signal lines GL, DL, and SL for transmitting various signals to the plurality of first pixel units P and various transistors TR for driving the first pixel units P may be disposed in the first display region AA1.

Various signal lines extending from the non-display region NA may be disposed in the plurality of first pixel units P. Accordingly, limitations in designing the transmissive portion T between the plurality of first pixel units P may occur. However, the display panel 1 according to this first example embodiment of the present specification may be relatively free in designing the transmissive portion T by disposing the plurality of first pixel units P in parallel in one direction.

In the display panel 1 according to the first example embodiment, two transmissive portions T may be disposed corresponding to one first pixel unit P. That is, two transmissive portions T may be disposed between two first pixel units P adjacent to each other in the column direction (Y). Accordingly, the display panel 1 according to the first example embodiment may have a plurality of transmissive portions T repeatedly disposed between any first row and second row of first pixel units P disposed in parallel and adjacent to each other.

The transmissive portions T according to the first example embodiment may have only one or more insulating layers disposed in the transmissive portions T to enhance the transmittance. That is, the transmissive portions T may be a patterned region of the second electrode 85 (e.g., regions where the second electrode 85 have openings OA). For example, the transmissive portions T may include a buffer film 20, a gate insulating film 30, an interlayer insulating film 40, a passivation layer 45, a first planarization layer 50, a second planarization layer 60, and a bank 70 between a substrate 10 and an encapsulation film 90.

The transmissive portions T may be regularly disposed between the linear data lines DL at least in a portion of the display area AA and the first pixel units P disposed in the row direction (X). The transmissive portions T according to the first example embodiment may be disposed in each space between the plurality of first pixel units P and the data lines DL. The transmissive portions T may be regularly disposed in the row and column directions (X and Y) over the first display region AA1. Accordingly, the display panel 1 according to the first example embodiment may have improved light intensity which is a zero-order peak wavelength of a PSF, and thus may improve the PSF. Further, the display panel 1 according to the first example embodiment may have improved transmittance in the first display region AA1 as more transmissive portions T are disposed compared to some other possible embodiments.

The transmissive portions T may not overlap the data lines DL. The transmissive portions T may be spaced apart from each other in the row direction (X) with the data lines DL therebetween. Here, the data lines DL may extend from the non-display region NA in the column direction (Y) and may be disposed spaced apart from each other in the row direction (X) in the first and second display regions AA1 and AA2.

In the first display region AA1, a first data line DL1 may cross a first light-emitting unit EA1, and a second data line DL2 and a third data line DL3 may cross a third light-emitting unit EA3. Accordingly, the transmissive portions T may be disposed between the first data line DL1 and the second data line DL2 adjacent to each other and between the third data line DL3 and the first data line DL1 adjacent to each other.

The data lines DL may be formed in a linear shape at least between the transmissive portions T compared to the plurality of first pixel units P.

As shown in FIGS. 6A, 9B, and 10B, a plurality of first pixel units P may be disposed in parallel in the row direction (X). Further, the rows of first pixel units P may be spaced apart from each other with a transmission portion T therebetween in the column direction (Y). In this case, a separation distance between adjacent first pixel units P in the column direction (Y) may be greater than a separation distance between adjacent first pixel units P in the row direction (X).

The first display region AA1 may include a plurality of first pixel units P and a plurality of transmissive portions T. Further, various signal lines GL, DL, and SL for transmitting various signals to the plurality of first pixel units P and various transistors TR for driving the first pixel units P may be disposed in the first display region AA1.

Various signal lines extending from the non-display region NA may be disposed in the plurality of first pixel units P. Accordingly, limitations in designing the transmissive portions T between the plurality of first pixel units P may occur. However, the display panel 1 according to this second example embodiment of the present specification may be relatively free in designing the transmissive portions T by disposing the plurality of first pixel units P in parallel in one direction.

In the display panel 1 according to the second example embodiment, two transmissive portions T may be disposed corresponding to one first pixel unit P. That is, two transmissive portions T may be disposed between two first pixel units P adjacent to each other in the column direction (Y). Accordingly, the display panel 1 according to the second example embodiment may have the plurality of transmissive portions T repeatedly disposed between any first row and second row of first pixel units P disposed in parallel and adjacent to each other.

The transmissive portions T may have only one or more insulating layers disposed in the transmissive portions T to enhance the transmittance. That is, the transmissive portions T may be a patterned region of the second electrode 85 (e.g., regions where the second electrode 85 have openings OA). For example, the transmissive portions T may include a buffer film 20, a gate insulating film 30, an interlayer insulating film 40, a passivation layer 45, a first planarization layer 50, a second planarization layer 60, and a bank 70 between a substrate 10 and an encapsulation film 90.

The transmissive portions T may be regularly disposed between the linear data lines DL at least in a portion of the display area AA and the first pixel units P disposed in parallel in the row direction (X). The transmissive portions T according to the second example embodiment may be disposed in each space between the plurality of first pixel units P and the data lines DL. The transmissive portions T may be regularly disposed in the row and column directions (X and Y) over the first display region AA1. Accordingly, the display panel 1 according to the second example embodiment may have improved light intensity, which is a zero-order peak wavelength of a PSF, and thus may improve the PSF. Further, the display panel 1 according to the second example embodiment may have improved transmittance in the first display region AA1 as more transmissive portions T are disposed compared to some other possible embodiments.

The transmissive portions T may not overlap the data lines DL. The transmissive portions T may be spaced apart from each other in the row direction (X) with the data lines DL therebetween. Here, the data lines DL may extend from the non-display region NA in the column direction (Y) and may be disposed spaced apart from each other in the row direction (X) in the first and second display regions AA1 and AA2.

In the first display region AA1, a first data line DL1 may cross a first light-emitting unit EA1, a second data line DL2 may cross a third light-emitting unit EA3, and the third data line DL3 may cross a second light emitting unit EA2 (e.g., a 2-2 light emitting unit EA2-2). Accordingly, the transmissive portions T may be disposed between the first data line DL1 and the second data line DL2 adjacent to each other and between the third data line DL3 and the first data line DL1 adjacent to each other.

The data lines DL may be formed in a linear shape at least between the transmissive portions T compared to the plurality of first pixel units P.

In a related art, a display panel in which an area of the transmission portion was improved to increase a recognition rate of the sensor was disclosed. In a related art, as the area of the transmissive portion increased, a line such as a data line passing between the transmissive portions was designed in a curved shape, instead of a linear shape, to bypass the periphery of the transmissive portions. Thus, where a line of a sensor unit is partially formed in a curved shape, since resistance increases toward a center of the display panel, a delay in the data signal or gate signal may occur.

However, in the display panel 1 according to example embodiments of the present specification, the data lines DL extending between the transmission portions T may be formed in a linear shape. Accordingly, the display panel 1 according to example embodiments of the present specification may have the effect of improving the PSF through linear data lines DL while also lowering the resistance compared to the curved shaped lines.

The transmissive portions T may be spaced apart from each other in the column direction (Y) with gate lines GL therebetween. Here, the gate lines GL may extend from the non-display region NA in the row direction (X) and may be disposed spaced part from each other in the column direction (Y) in the first and second display regions AA1 and AA2.

For example, referring to FIGS. 9A and 10A, in the first display region AA1, a first gate line GL1 may cross the second light-emitting unit EA2, a second gate line GL2 may cross the first and third light-emitting units EA1 and EA3, and a third gate line GL3 may cross at least one of the first and third light-emitting units EA1 and EA3. As another example, referring to FIGS. 9B and 10B, in the first display region AA1, the first and third gate lines GL1 and GL3 may cross the second light-emitting unit EA2 and the second gate line GL2 may cross the first and third light-emitting units EA1 and EA3. Accordingly, the transmissive portion T may be disposed between the two adjacent sets of gate lines GL1, GL2, and GL3 respectively passing through two adjacent rows of first pixel units P in the column direction (Y).

However, in the present specification, the data lines DL and the gate lines GL are not limited to what is shown in the example embodiments. For example, the data lines DL and the gate line GL may have partially bent regions in at least the first pixel unit P, and signals may be transmitted to two subpixels (light-emitting units) with one data line, and signals may be transmitted to two subpixels (light-emitting units) with one gate line. Also, in the present specification, the gate lines GL may overlap the plurality of first pixel units P, and the data lines DL may be formed in a form close to a linear shape between the transmission portions T.

A signal line SL may include various lines disposed in the first display region AA1. For example, the signal line SL may include various types of voltage supply lines for driving the plurality of first pixel units P or lines connected to a camera and a sensor.

The signal line SL may extend from the non-display region NA and may be disposed to cross the first pixel units P of the first display region AA1 or between adjacent first pixel units P. Although the figures illustrating examples show that the signal line SL is formed in the row direction (X), the display panel of the present specification is not limited thereto. For example, the signal line SL may be formed in the column direction (Y), or at least one signal line SL may be formed in the row direction (X) and at least one other signal line SL in the column direction (Y).

The first driving circuit unit MA may include circuit components disposed in the first pixel unit P excluding the gate line GL, the data line DL, and the signal line SL in the form of lines extending from the non-display region NA. For example, the first driving circuit unit MA may include a driving element, a connection electrode, or the like as a circuit for driving the light-emitting elements 80 (e.g., 80a, 80b, and 80c). The driving element may include at least one transistor TR for each light-emitting element 80. For example, the driving element may include a driving transistor, a scan transistor for transmitting a data voltage to the driving transistor, and a storage capacitor for maintaining a constant voltage for one frame.

The first driving circuit unit MA may overlap the first pixel unit P. The first driving circuit unit MA may occupy a larger area than the first pixel unit P, but may not overlap the transmission portion T.

In the first display region AA1, the plurality of first pixel units P may include light-emitting units EA1, EA2, and EA3 of different colors. The first light-emitting unit EA1 may emit red light, the second light-emitting unit EA2 may emit green light, and the third light-emitting unit EA3 may emit blue light. However, the display panel of the present specification is not limited thereto.

The second light-emitting unit EA2 may include a 2-1 light-emitting unit EA2-1 and a 2-2 light-emitting unit EA2-2. The 2-1 light-emitting unit EA2-1 and the 2-2 light-emitting unit EA2-2 according to the first example embodiment (see, e.g., FIGS. 6B, 9A, and 10A) may be disposed in parallel in the row direction (X).

A connection electrode LL disposed in the first display region AA1 may be disposed on the first planarization layer 50 and may include a plurality of connection electrodes LL (e.g., LL1 and LL2). The plurality of connection electrodes LL may include a first connection electrode LL1 and a second connection electrode LL2.

One of the first connection electrode LL1 and the second connection electrode LL2 may be disposed as a dummy connection electrode. The plurality of connection electrodes LL may electrically connect the first electrode 81 of the light-emitting element 80 (80a, 80b, or 80c) and the corresponding transistor TR through a contact hole CNT.

For example, the connection electrode LL may be formed of a single layer of a metal material, such as molybdenum (Mo), aluminum (Al), chromium (Cr), gold (Au), titanium (Ti), nickel (Ni), neodymium (Nd), copper (Cu), or an alloy thereof, or may be formed in a multilayer structure using one or more of such metal materials.

The 2-1 light-emitting unit EA2-1 and the 2-2 light-emitting unit EA2-2 according to the first example embodiment may be disposed in parallel in the row direction (X) on one side of the first light-emitting unit EA1 and the third light-emitting unit EA3 in the column direction (Y). Accordingly, an area occupied by a connection pattern (e.g., a first electrode 81) which connects the 2-1 light-emitting unit EA2-1 and the 2-2 light-emitting unit EA2-2 may be relatively reduced. Thus, the reduced area of the connection pattern may have an effect of improving the PSF for the first display region AA1.

In another aspect, the third light-emitting unit EA3 may have the largest area among the light-emitting units. The light-emitting efficiency of blue may be the lowest compared to red and green. Accordingly, with the third light-emitting unit EA3 having the largest area, the light-emitting efficiency may be improved.

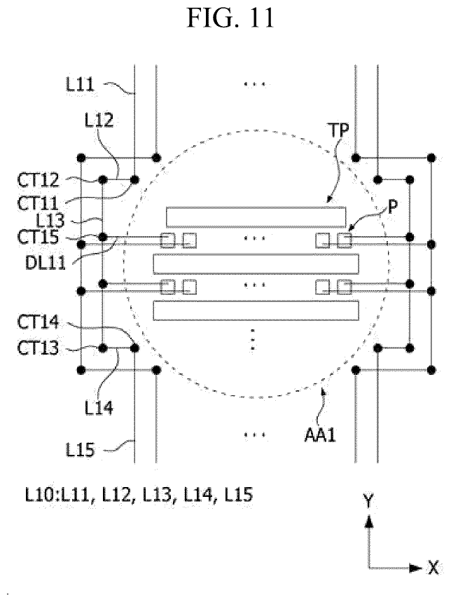

FIG. 11 is a plan view of a display panel according to an example embodiment of the present specification.

As illustrated in FIG. 11, a display panel 1 according to a third example embodiment of the present specification may have a plurality of signal lines L10 disposed around a first display region AA1. The signal lines L10 according to this example embodiment may be disposed from a second display region AA2 into the first display region AA1, and may not overlap a transmissive pattern region TP. The signal lines L10 may be disposed to overlap first pixel units P. Where rows of the first pixel units P are arranged in the row direction (X), the transmissive pattern regions TP may be disposed between the first pixel units P adjacent to each other in the column direction (Y).

The signal lines L10 may extend from a non-display region NA, and may be disposed in the second display region AA2 and the first display region AA1 and connected to a first driving circuit unit of the first pixel unit P. For example, the signal lines L10 may include various signal lines such as a signal line, a data signal line, a gate signal line, a power voltage line, or the like for transmitting a signal to a camera or sensor disposed in the first display region AA1. The signal lines L10 according to this example embodiment of the present embodiment may be a data signal line connected to a data line intersecting a boundary portion between the transmissive portions in the previous example embodiment. However, the display panel of the present specification is not limited thereto.

The signal lines L10 may include a first signal line L11, a second signal line L12, a third signal line L13, a fourth signal line L14, and a fifth signal line L15. The first to fifth signal lines L11, L12, L13, L14, and L15 may be connected respectively through contact portions CT11, CT12, CT13, and CT14 at intersections thereof.

Specifically, the first signal line L11 proceeding to the first display region AA1 may be formed in the column direction (Y) and may be electrically connected to the second signal line L12 formed in the row direction (X) through a first contact portion CT11. The second signal line L12 may be electrically connected to the third signal line L13 formed in the column direction (Y) through a second contact portion CT12. The third signal line L13 may be electrically connected to the fourth signal line L14 formed in the row direction (X) through a third contact portion CT13. The fourth signal line L14 may be electrically connected to the fifth signal line L15 formed in the column direction (Y) through a fourth contact portion CT14.

A plurality of data lines DL11 respectively corresponding to the first pixel units P may be disposed. The data lines DL11 corresponding to the first pixel units P disposed in any first column may be connected to one signal line L10 (e.g., L13). That is, the first pixel unit P disposed in any first row and first column, the first pixel unit P disposed in the second row and first column, and the first pixel unit P disposed in the nth row and first column may be connected to one signal line (e.g., L13). However, the display panel of the present specification is not limited thereto. For example, the data lines disposed across the pixel units disposed in any first row may transmit a signal to the pixel units disposed in the first row.

Each data line DL11 may be connected to a signal line L10 through the fifth contact portion CT15. The data line DL11 may be connected, for example, to the third signal line L13. However, the display panel of the present specification is not limited thereto. For example, one data line DL11 may be connected to any one of the first to fifth signal lines L11, L12, L13, L14, and L15.

Each data line DL11 and the third signal line L13 may be disposed on different layers. Each data line DL11 and the third signal line L13 may be electrically connected through a contact hole formed in the contact portion CT15.

The transmissive pattern regions TP may be a region between the first pixel units P adjacent to each other in the column direction (Y). Signal lines may not be disposed in the transmissive pattern regions TP. Further, the transmissive pattern regions TP may include any and all of the transmissive portions T implemented in the above example embodiments.

Accordingly, the display panel 1 according to example embodiments may have an effect in which a free design of transmissive portions having different transmittances in the transmissive pattern regions TP is possible. Accordingly, the display panel 1 according to example embodiments of the present specification may have an effect of enhancing the image resolution of sensors by improving the PSF.

A display panel according to one or more example embodiments of the present specification includes a substrate including a first display region and a second display region adjacent to the first display region, the first and second display regions each being configured to display an image. The first display region may include a plurality of first pixel units and a plurality of transmissive portions between the plurality of first pixel units, each of the plurality of first pixel units including a first light-emitting element configured to emit a first color light and a transistor for driving the first light-emitting element. The second display region may include a plurality of second pixel units, each including a first regular light-emitting element configured to emit the first color light and a transistor for driving the first regular light-emitting element. A number of contact holes disposed between the first light-emitting element and the transistor for driving the first light-emitting element in the first display region may be greater than a number of contact holes disposed between the first regular light-emitting element and the transistor for driving the first regular light-emitting element in the second display region.

In the display panel according to one or more embodiments of the present specification, at least two contact holes may be disposed between and overlap the first light-emitting element and the transistor for driving the first light-emitting element in the first display region, and the at least two contact holes may extend through at least one insulating layer disposed between the first light-emitting element and the transistor for driving the first light-emitting element.

In the display panel according to one or more embodiments of the present specification, the first display region may further include a plurality of connection electrodes disposed respectively in the at least two contact holes, the at least two contact holes may include a first contact hole and a second contact hole, and a first connection electrode in the first contact hole, among the plurality of connection electrodes, may connect the first light-emitting element and the transistor for driving the first light-emitting element.

In the display panel according to one or more embodiments of the present specification, the second contact hole may be a dummy contact hole, and a second connection electrode in the dummy contact hole, among the plurality of connection electrodes, may be a dummy electrode configured to be in a floating state.

In the display panel according to one or more embodiments of the present specification, the second contact hole may be a redundant contact hole, and a second connection electrode in the redundant contact hole, among the plurality of connection electrodes, may be a redundant connection electrode connecting the first light-emitting element and the transistor for driving the first light-emitting element.

In the display panel according to one or more embodiments of the present specification, the first display region may include a plurality of transistors for respectively driving the plurality of first pixel units, the second display region may include a plurality of transistors for respectively driving the plurality of second pixel units, and a density of the transistors in the first display region may be lower than a density of transistors in the second display region.

In the display panel according to one or more embodiments of the present specification, the plurality of transmissive portions may not overlap the plurality of first pixel units in a cross-sectional direction of the display panel, and the plurality of transmissive portions may include only transparent layers. The transparent layers disposed in the plurality of transmissive portions may include a substrate 10, insulating layers, intermediate layers 83 of the light-emitting elements 80, and the like. For example, the transparent layers may refer to layers made of materials having higher transmittance than the second electrode 85, and the insulating layers may include layers 20, 30, 40, 45, 50, 60, and 70.

In the display panel according to one or more embodiments of the present specification, each of the first pixel units may further include a second light-emitting element configured to emit a second color light and a third light-emitting element configured to emit a third color light.

In the display panel according to one or more embodiments of the present specification, the second light-emitting element may include a 2-1 light-emitting element and a 2-2 light-emitting element, each configured to emit the second color light, and the 2-1 light-emitting element and the 2-2 light-emitting element may be connected with each other via a connection pattern and be connected to one driving transistor.

In the display panel according to one or more embodiments of the present specification, the second color light may be a light in a green wavelength band.

In the display panel according to one or more embodiments of the present specification, the first light-emitting element and the third light-emitting element may be disposed in parallel along a first direction, and the 2-1 light-emitting element and the 2-2 light-emitting element may be disposed in parallel along the first direction and be disposed at one side of the first light-emitting element and the third light-emitting element in a second direction different from the first direction.

In the display panel according to one or more embodiments of the present specification, each of the second pixel units may further include a second regular light-emitting element configured to emit the second color light and a third regular light-emitting element configured to emit the third color light. The first, second, and third regular light-emitting elements in at least one of the second pixel units may be arranged in a different configuration from the first, second, and third light-emitting elements in at least one of the first pixel units in a plan view.

The display panel according to one or more embodiments of the present specification may further include a plurality of signal lines connected respectively to the plurality of first pixel units. The plurality of signal lines may extend from the second display region into the first display region and may not overlap the plurality of transmissive portions.

In the display panel according to one or more embodiments of the present specification, the plurality of transmissive portions may include a first transmissive portion and a second transmissive portion having lower transmittance than the first transmissive portion. At least one of the plurality of signal lines may be disposed between the first transmissive portion and the second transmissive portion.

The display panel according to one or more embodiments of the present specification may further include an optical device under the first display region of the substrate.

In another aspect of the present disclosure, a display apparatus according to one or more embodiments of the present specification includes: a substrate with a first display region and a second display region each configured to display an image; an optical device under the first display region of the substrate; a plurality of first pixels in the first display region and a plurality of second pixels in the second display region, each of the first pixels and the second pixels including a first light-emitting element configured to emit a first color light; a plurality of transmissive portions between the first pixels in the first display region; a plurality of driving transistors in the first display region and the second display region and respectively configured to drive the first pixels and the second pixels, the driving transistors including a first driving transistor connected to the first light-emitting element in one of the first pixels and a second driving transistor connected to the first light-emitting element in one of the second pixels; at least one insulating layer between the first driving transistor and the first light-emitting element in the one of the first pixels and between the second driving transistor and the first light-emitting element in the one of the second pixels; and a plurality of contact holes through the at least one insulating layer. More of the contact holes may be disposed between the first driving transistor and the first light-emitting element in the one of the first pixels than between the second driving transistor and the first light-emitting element in the one of the second pixels.

In the display apparatus according to one or more embodiments of the present specification, the contact holes may include a first contact hole and a second contact hole each disposed between and overlapping the first driving transistor and the first light-emitting element in the one of the first pixels. The display apparatus may further include a first connection electrode in the first contact hole and a second connection electrode in the second contact hole, the first connection electrode connecting the first driving transistor with the first light-emitting element in the one of the first pixels.

In the display apparatus according to one or more embodiments of the present specification, the second contact hole may be a dummy contact hole, and the second connection electrode may be a dummy electrode configured to be in a floating state; or the second contact hole may be a redundant contact hole, and the second connection electrode may be a redundant connection electrode connecting the first driving transistor with the first light-emitting element in the one of the first pixels.

In the display apparatus according to one or more embodiments of the present specification, a density of the driving transistors in the first display region may be smaller than a density of driving transistors in the second display region.

In the display apparatus according to one or more embodiments of the present specification, each of the one of the first pixels and the one of the second pixels may further include a second light-emitting element configured to emit a second color light and a third light-emitting element configured to emit a third color light. The first, second, and third light-emitting elements in the one of the second pixels may be arranged in a different configuration from the first, second, and third light-emitting elements in the one of the first pixels in a plan view.

A display panel according to one or more example embodiments of the present specification can have an effect of mitigating a potential difference in brightness between a general (or regular or normal) display region and an under display camera (UDC) and under display infrared radiation (UDIR) region by disposing additional contact holes in the UDC and UDIR region.

The effects according to various example embodiments of the present specification are not limited to the above-mentioned effects, and other effects which are not mentioned can be clearly understood by those skilled in the art from the above description.

While various example embodiments of the present specification have been described above in detail with reference to the accompanying drawings, the present disclosure is not necessarily limited to these example embodiments, and various changes and modifications may be made without departing from the technical spirit of the present disclosure.

Accordingly, the example embodiments disclosed herein are to be considered illustrative examples and not restrictive of the technical spirit of the present disclosure, and the scope of the technical spirit of the present disclosure is not limited by these example embodiments.

Accordingly, the above-described embodiments should be understood to be examples and not limiting in any aspect.

The protected scope of the present disclosure may be construed by the appended claims and their equivalents, and all technical ideas within the scope of their equivalents should be construed as being included in the scope of the present disclosure.

What is claimed is:

1. A display panel, comprising:
a substrate including a first display region and a second display region adjacent to the first display region, the first and second display regions each being configured to display an image,
wherein the first display region includes a plurality of first pixel units and a plurality of transmissive portions between the plurality of first pixel units, each of the plurality of first pixel units including a first light-emitting element configured to emit a first color light and a transistor for driving the first light-emitting element,
wherein the second display region includes a plurality of second pixel units, each including a first regular light-emitting element configured to emit the first color light and a transistor for driving the first regular light-emitting element, and
wherein a number of contact holes disposed between the first light-emitting element and the transistor for driving the first light-emitting element in the first display region is greater than a number of contact holes disposed between the first regular light-emitting element and the transistor for driving the first regular light-emitting element in the second display region.

2. The display panel of claim 1, wherein:
at least two contact holes are disposed between and overlap the first light-emitting element and the transistor for driving the first light-emitting element in the first display region; and
the at least two contact holes extend through at least one insulating layer disposed between the first light-emitting element and the transistor for driving the first light-emitting element.

3. The display panel of claim 2, wherein:
the first display region further includes a plurality of connection electrodes disposed respectively in the at least two contact holes;
the at least two contact holes include a first contact hole and a second contact hole; and
a first connection electrode in the first contact hole, among the plurality of connection electrodes, connects the first light-emitting element and the transistor for driving the first light-emitting element.

4. The display panel of claim 3, wherein:
the second contact hole is a dummy contact hole; and
a second connection electrode in the dummy contact hole, among the plurality of connection electrodes, is a dummy electrode configured to be in a floating state.

5. The display panel of claim 3, wherein:
the second contact hole is a redundant contact hole; and
a second connection electrode in the redundant contact hole, among the plurality of connection electrodes, is a redundant connection electrode connecting the first light-emitting element and the transistor for driving the first light-emitting element.

6. The display panel of claim 1, wherein:
the first display region includes a plurality of transistors for respectively driving the plurality of first pixel units;
the second display region includes a plurality of transistors for respectively driving the plurality of second pixel units; and
a density of the transistors in the first display region is lower than a density of transistors in the second display region.

7. The display panel of claim 1, wherein:
the plurality of transmissive portions do not overlap the plurality of first pixel units in a cross-sectional direction of the display panel; and
the plurality of transmissive portions include only transparent layers.

8. The display panel of claim 1, wherein each of the first pixel units further includes a second light-emitting element configured to emit a second color light and a third light-emitting element configured to emit a third color light.

9. The display panel of claim 8, wherein:
the second light-emitting element includes a 2-1 light-emitting element and a 2-2 light-emitting element, each configured to emit the second color light; and
the 2-1 light-emitting element and the 2-2 light-emitting element are connected with each other via a connection pattern and are connected to one driving transistor.

10. The display panel of claim 9, wherein the second color light is a light in a green wavelength band.

11. The display panel of claim 9, wherein, in a plan view:
the first light-emitting element and the third light-emitting element are disposed in parallel along a first direction; and
the 2-1 light-emitting element and the 2-2 light-emitting element are disposed in parallel along the first direction and are disposed at one side of the first light-emitting element and the third light-emitting element in a second direction different from the first direction.

12. The display panel of claim 8, wherein:
each of the second pixel units further includes a second regular light-emitting element configured to emit the second color light and a third regular light-emitting element configured to emit the third color light; and
the first, second, and third regular light-emitting elements in at least one of the second pixel units are arranged in a different configuration from the first, second, and third light-emitting elements in at least one of the first pixel units in a plan view.

13. The display panel of claim 1, further comprising a plurality of signal lines connected respectively to the plurality of first pixel units,
wherein the plurality of signal lines extend from the second display region into the first display region and do not overlap the plurality of transmissive portions.

14. The display panel of claim 13, wherein:
the plurality of transmissive portions include a first transmissive portion and a second transmissive portion having lower transmittance than the first transmissive portion; and
at least one of the plurality of signal lines is disposed between the first transmissive portion and the second transmissive portion.

15. The display panel of claim 1, further comprising:
an optical device under the first display region of the substrate.

16. A display apparatus, comprising:
a substrate with a first display region and a second display region each configured to display an image;
an optical device under the first display region of the substrate;
a plurality of first pixels in the first display region and a plurality of second pixels in the second display region, each of the first pixels and the second pixels including a first light-emitting element configured to emit a first color light;
a plurality of transmissive portions between the first pixels in the first display region;
a plurality of driving transistors in the first display region and the second display region and respectively configured to drive the first pixels and the second pixels, the driving transistors including a first driving transistor connected to the first light-emitting element in one of the first pixels and a second driving transistor connected to the first light-emitting element in one of the second pixels;
at least one insulating layer between the first driving transistor and the first light-emitting element in the one of the first pixels and between the second driving transistor and the first light-emitting element in the one of the second pixels; and
a plurality of contact holes through the at least one insulating layer,
wherein more of the contact holes are disposed between the first driving transistor and the first light-emitting element in the one of the first pixels than between the second driving transistor and the first light-emitting element in the one of the second pixels.

17. The display apparatus of claim 16, wherein:
the contact holes include a first contact hole and a second contact hole each disposed between and overlapping the first driving transistor and the first light-emitting element in the one of the first pixels; and
the display apparatus further comprises a first connection electrode in the first contact hole and a second connection electrode in the second contact hole, the first connection electrode connecting the first driving transistor with the first light-emitting element in the one of the first pixels.

18. The display apparatus of claim 17, wherein:
the second contact hole is a dummy contact hole, and the second connection electrode is a dummy electrode configured to be in a floating state; or
the second contact hole is a redundant contact hole, and the second connection electrode in a redundant connection electrode connecting the first driving transistor with the first light-emitting element in the one of the first pixels.

19. The display apparatus of claim 16, wherein a density of the driving transistors in the first display region is smaller than a density of driving transistors in the second display region.

20. The display apparatus of claim 16, wherein:
each of the one of the first pixels and the one of the second pixels further includes a second light-emitting element configured to emit a second color light and a third light-emitting element configured to emit a third color light; and
the first, second, and third light-emitting elements in the one of the second pixels are arranged in a different configuration from the first, second, and third light-emitting elements in the one of the first pixels in a plan view.
